(19) United States
(12) Patent Application Publication
(10) Pub. No.: US 2010/0148782 A1
(43) Pub. Date: Jun. 17, 2010

(54) RUGGED QUARTZ CLOCK

(75) Inventor: NORIYUKI MATSUMOTO, YOKOHAMA-SHI (JP)

Correspondence Address: SCHLUMBERGER K.K., 2-2-1 FUCHINOBE, CHUO-KU, SAGAMIHARA-SHI, KANAGAWA-KEN, 252-0206, JP

(73) Assignee: SCHLUMBERGER TECHNOLOGY CORPORATION, Sugar Land, TX (US)

(21) Appl. No.: 12/335,425

(22) Filed: Dec. 15, 2008

(51) Int. Cl. H01L 41/053; G01V 3/00

(52) U.S. Cl. 324/333; 310/348

(57) ABSTRACT

A resonator clock suitable for use in downhole conditions is described. The resonator clock includes a resonator portion of piezoelectric material; two electrodes in electrical communication with the resonator portion such that the resonator portion resonates when voltage is applied between the two electrodes; and four supports to support the resonator portion. The supports are dimensioned and positioned to support the resonator portion under shock and vibration encountered in downhole use. The supports and the resonator portion are formed from the same continuous piece of piezoelectric material.

### BACKGROUND OF THE INVENTION

1. Field of the Invention

This patent specification relates ruggedized quartz clocks. More particularly this patent specification relates to rugged quartz clocks particularly suited to downhole applications.

2. Background of the Invention

For many of down hole applications, a precision time reference clock is used. For example, a precision clock may be used downhole to provide a time reference for counting frequency outputs from resonator type pressure and/or temperature sensors. In another example, a precision clock can be used as a reference to provide synchronization between surface and downhole operations.

FIG. 1 shows a precision time reference clock mechanically packaged in conventional metal can package. Note that the view shown in FIG. 1 is of the interior of the clock. Normally, the quartz resonator 110 is hidden inside a metal can-type enclosure. The can is usually bonded to the metal base 112 by cold welding for the sake of secured seal. This package type has a relatively good track record for keeping the interior in vacuum, which is one of the important features to provide good performances of the clock.

However, one significant drawback of the metal can type package is the mechanical robustness. As can be seen in FIG. 1, the quartz resonator 110 is supported by three legs 114, 116 and 118. Other numbers of legs, such as 2 and 4 legs can be used depending on the size and kind of the package. The resonator 110 is normally glued to the legs 114, 116 and 118 by using conductive bonding agent in order to flow current while mechanically securing it in the package. Even with four legs, the resonator 110 can become dislodged from the legs due to a strong mechanical shock such as is incurred through downhole use. If the mechanical robustness is enhanced by increasing the bonding agent between the resonator and the legs, this will have a negative side effect to the electrical characteristics.

Additionally, the resistance of the conductive bonding agent tends to slightly change long term under high temperatures, and therefore the resonance of the crystal also tends to change over time. Furthermore, the conductive bonding agent is typically organic in composition, such epoxy, and therefore degasses over time in the vacuum environment.

Other packaging technologies are known in the industry, such as a ceramic package. But these alternative packages have been found in general to be less effective than the conventional metal enclosure for the sealing performances especially at elevated temperatures.

Thus, there is a need for a more mechanically robust quartz clock design for downhole use under both high temperatures and high shock exposure.

### SUMMARY OF THE INVENTION

According to embodiments, a resonator clock for use in downhole conditions is provided. The resonator clock includes a resonator portion of piezoelectric material; two electrodes in electrical communication with the resonator portion such that the resonator portion resonates when voltage is applied between the two electrodes; and two or more supports to support the resonator portion. The supports are dimensioned and positioned to support the resonator portion under shock and vibration encountered in downhole use. The supports and the resonator portion are formed from the same continuous piece of piezoelectric material.

Additionally, according to some embodiments downhole tool is provided which makes use of a resonator clock as described above. Furthermore, the invention is also embodied in a method for making measurements downhole using a resonator clock as described above.

Further features and advantages of the invention will become more readily apparent from the following detailed description when taken in conjunction with the accompanying drawings.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 shows a precision time reference clock mechanically packaged in conventional metal can package;

FIG. 2 illustrates a wellsite system in which the present invention can be employed;

FIG. 3 shows another typical downhole setting for rugged quartz clock, according to embodiments;

FIG. 4 shows an example of a quartz clock resonator, according to some embodiments;

FIG. 5 shows further details of the example of a quartz clock resonator shown in FIG. 4; and

FIG. 6 is a cross sectional view along the line A-A′ of the quartz clock resonator shown in FIGS. 4 and 5.

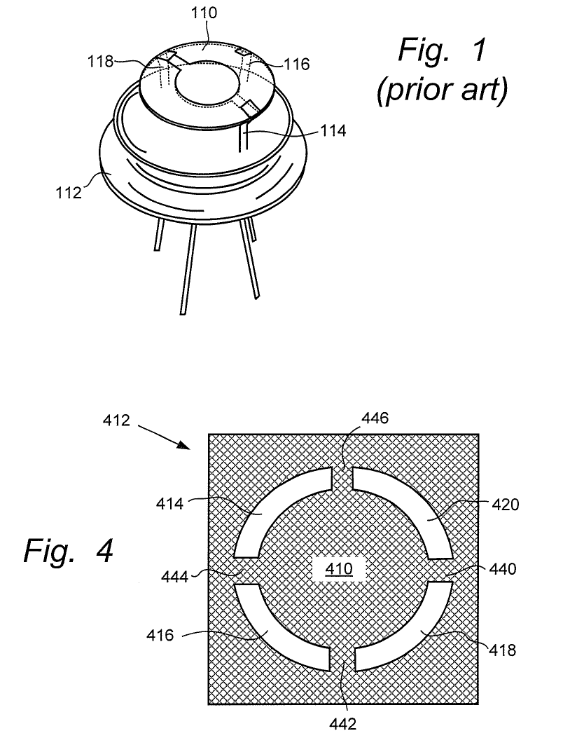

### DETAILED DESCRIPTION OF THE PREFERRED EMBODIMENTS

In the following detailed description of the preferred embodiments, reference is made to accompanying drawings, which form a part hereof, and within which are shown by way of illustration specific embodiments by which the invention may be practiced. It is to be understood that other embodiments may be utilized and structural changes may be made without departing from the scope of the invention.

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice. Further, like reference numbers and designations in the various drawings indicated like elements.

For many of down hole applications, a precision time reference clock is used. For example, a precision clock may be used downhole to provide a time reference for counting frequency outputs from resonator type pressure and/or temperature sensors. In another example, a precision clock can be used as a reference to provide synchronization between surface and downhole operations.

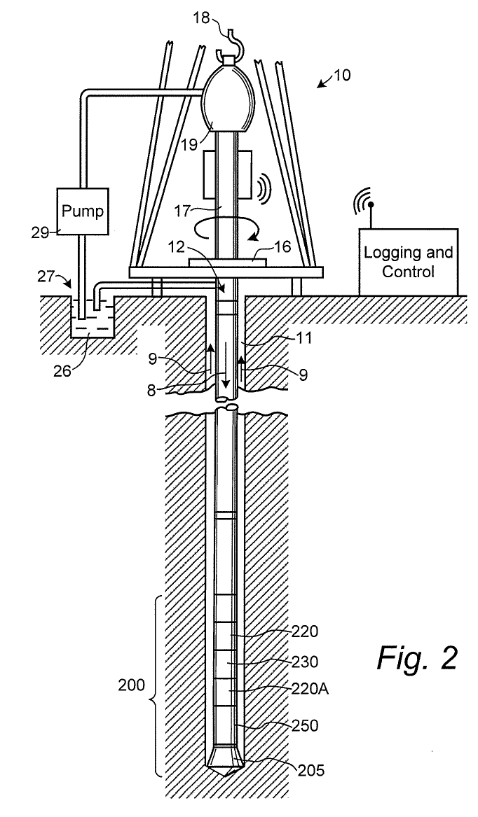

FIG. 2 illustrates a wellsite system in which the present invention can be employed. The wellsite can be onshore or offshore. In this exemplary system, a borehole 11 is formed in subsurface formations by rotary drilling in a manner that is well known. Embodiments of the invention can also use directional drilling, as will be described hereinafter.

A drill string 12 is suspended within the borehole 11 and has a bottom hole assembly 200 which includes a drill bit 205 at its lower end. The surface system includes platform and derrick assembly 10 positioned over the borehole 11, the assembly 10 including a rotary table 16, kelly 17, hook 18 and rotary swivel 19. The drill string 12 is rotated by the rotary table 16, energized by means not shown, which engages the kelly 17 at the upper end of the drill string. The drill string 12 is suspended from a hook 18, attached to a traveling block (also not shown), through the kelly 17 and a rotary swivel 19 which permits rotation of the drill string relative to the hook. As is well known, a top drive system could alternatively be used.

In the example of this embodiment, the surface system further includes drilling fluid or mud 26 stored in a pit 27 formed at the well site. A pump 29 delivers the drilling fluid 26 to the interior of the drill string 12 via a port in the swivel 19, causing the drilling fluid to flow downwardly through the drill string 12 as indicated by the directional arrow 8. The drilling fluid exits the drill string 12 via ports in the drill bit 205, and then circulates upwardly through the annulus region between the outside of the drill string and the wall of the borehole, as indicated by the directional arrows 9. In this well known manner, the drilling fluid lubricates the drill bit 205 and carries formation cuttings up to the surface as it is returned to the pit 27 for recirculation.

The bottom hole assembly 200 of the illustrated embodiment a logging-while-drilling (LWD) module 220, a measuring-while-drilling (MWD) module 230, a roto-steerable system and motor, and drill bit 205.

The LWD module 220 is housed in a special type of drill collar, as is known in the art, and can contain one or a plurality of known types of logging tools. It will also be understood that more than one LWD and/or MWD module can be employed, e.g. as represented at 220A. (References, throughout, to a module at the position of 220 can alternatively mean a module at the position of 220A as well.) The LWD module includes capabilities for measuring, processing, and storing information, as well as for communicating with the surface equipment. In the present embodiments, the LWD module includes an acoustic measuring device, which includes a rugged quartz clock as described herein.

The MWD module 230 is also housed in a special type of drill collar, as is known in the art, and can contain one or more devices for measuring characteristics of the drill string and drill bit. The MWD tool further includes an apparatus (not shown) for generating electrical power to the downhole system. This may typically include a mud turbine generator powered by the flow of the drilling fluid, it being understood that other power and/or battery systems may be employed. In the present embodiment, the MWD module includes one or more of the following types of measuring devices: a weight-on-bit measuring device, a torque measuring device, a vibration measuring device, a shock measuring device, a stick slip measuring device, a direction measuring device, and an inclination measuring device. In the present embodiments, the LWD module can also include a rugged quartz clock as described herein.

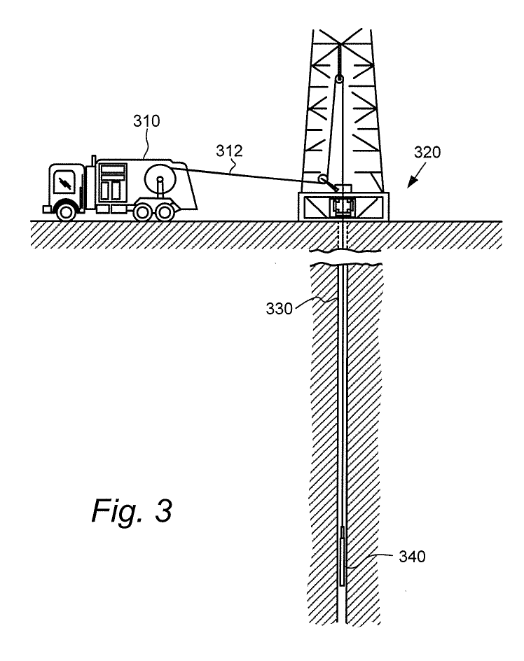

FIG. 3 shows another typical downhole setting for rugged quartz clock, according to embodiments. Shown in FIG. 3 is wireline truck 310 deploying wireline cable 312 into well 330 via well head 320. Wireline tool 340 is disposed on the end of the cable 312. According to one example, wireline tool 340 is a downhole sampling tool such as the Modular Formation Dynamics Tester tool from Schlumberger. Within tool 340 are one or more downhole pressure transducers each housed in a sealed container. The harsh downhole environments such as shown in FIGS. 2 and 3, typically expose the downhole quartz clock to various extreme conditions such as shock and large temperature and pressure fluctuations.

FIG. 4 shows an example of a quartz clock resonator, according to some embodiments. Resonator portion 410 is circular in shape and is part of quartz plate 412 which is a single piece of crystalline quartz. The circular center portion of quartz plate 412 forms circular resonator portion 410 due to four circular openings 414, 416, 418 and 420. The openings 414, 416, 418 and 420 thereby create four support members 440, 442, 444 and 446, which support resonator portion 410 and are formed from the same single continuous piece of quartz plate 412. Further the resonator portion 410 is of convex shape which can be seen more clearly in FIG. 6, described below. According to some embodiments, the quartz plate 412 is made from stress-compensated cut (“SC-cut”) quartz, which has the advantage of being relatively force insensitive in this application. The SC-cut has been found to be suitable for dual-mode clocks.

It is noted that the structures described herein are applicable to both single mode (i.e single frequency) and dual-mode (i.e. dual frequency) clocks. For embodiments using single-mode clocks the following crystalline orientations have been found to be suitable AT-cut and BT-cut. For embodiments using dual-mode clocks, the following orientations have been found to be suitable, SC-Cut, RT-cut, X+30o-cut, and SBTC-cut.

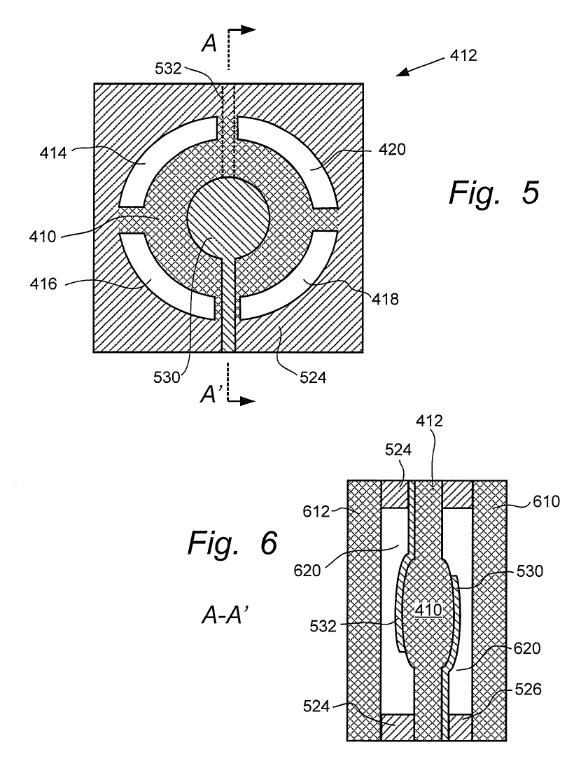

FIG. 5 shows further details of the example of a quartz clock resonator shown in FIG. 4. The electrodes 530 and 532 (which shown more clearly in FIG. 6) are deposited directly on the surface of the resonator portion 410 using for example, vacuum deposition techniques. According to some embodiments, a chromium or titanium substrate is first deposited, upon which a gold layer is then deposited. Spacer 524 is hermetically bonded to the surface of quartz plate 412 in the area outside of the four openings 414, 416, 418 and 420. Spacer 524 is bonded to the surface of crystal quartz plate 412, for example, using a non conductive, non organic bonding agent such as silicon dioxide. According to some embodiments, spacer 524 is made of silicon dioxide as well. According to some other embodiments, the thickness of the boding agent used, such as silicon dioxide, is thicker than the convex portion of resonator portion 410 and therefore the spacer 524 may consist solely of the boding agent and no additional spacer is required. Note that since there is no organic conductive bonding agent used such as is common in the prior art, the problem of degassing by such agents is greatly decreased. Furthermore, since there is no organic conductive bonding agent used to support the resonator portion 410, the problem of long term thermal effects causing a change in resistivity and associated resonator characteristics, is greatly diminished.

Note that although four circular openings or slits are shown in FIGS. 4 and 5, according to some embodiments, other number of circular slots are used. For example, according to some embodiments, there are only two slots (and therefore two support members). Such designs may be used, for example, in applications where the expected shock exposure is lower. However, it has been found that providing four slots and therefore four support points minimize the stress effect to the C-mode frequency. Thus, the four-slot, four support design tends to minimize the frequency variation of the C-mode over a relatively wide temperature range. The preferred use of four slots and four supports to decrease C-mode variations for a downhole clock is in stark contrast to a downhole pressure gauge design, which benefits from just the opposite: large C-mode variations.

According to other embodiments, greater numbers of slots are provided. However it has been found that having a maximum of four support members allows for decreased force sensitivity, particularly when using SC-cut quartz. While having more than four support members (and therefore, greater than four slots) will slightly increase the robustness of the design, it has been found that this will significantly increase the force sensitivity of the clock. The result of increased force sensitivity, is that the clock will be generally more susceptible to changes and error due to temperature changes causing thermal expansion.

FIG. 6 is a cross sectional view along the line A-A′ of the quartz clock resonator shown in FIGS. 4 and 5. Note that spacer 524 is bonded on one side of the quartz quartz plate 412 and spacer 526 is bonded on the other side of quartz plate 412. Also shown are plates 610 and 612 which are solid and bonded to spacers 526 and 524 respectively such that an interior cavity 620 is formed. Plates 610 and 612, spacers 524 and 526, and quartz plate 412 are all hermetically bonded using a bonding agent such as silicon dioxide such that cavity 620 is maintained in as a vacuum. The material for plates 610 and 612 are preferably the same material and the same crystalline orientation as quartz plate 412, in this case crystalline quartz, so as to minimize stress due to thermal expansion. As mentioned above, according to some embodiments, the bonding agent, such as silicon dioxide, after curing is substantially thicker than the convex portion of resonator portion 410, such that no separate spacer is required. In such embodiments, the reference numbers 524 and 526 refer to the bonding agent 524 and bonding agent 526.

Thus, the described embodiments eliminate the use of a bonding agent to support the resonator by making the resonator and its peripheral support from one piece of quartz plate, two additional plates for the enclosure. These three pieces of quartz are hermetically sealed with a non-conductive bonding agent. By integrating the resonator supports into the same crystalline plate as the resonator itself, the structure is robust enough to withstand the demanding shock and vibration environments of downhole use, especially with LWD/MWD applications.

According to some embodiments, the entire assembly shown in FIG. 6 is mounted and packaged in a standard electrical package as is known in the art. According to some embodiments, a metal can package such as is used with prior art downhole quartz clocks is used to surround the assembly.

According to some embodiments, alternative piezo-electric materials are used instead of quartz, such as Langasite and/or Langatite

Whereas many alterations and modifications of the present invention will no doubt become apparent to a person of ordinary skill in the art after having read the foregoing description, it is to be understood that the particular embodiments shown and described by way of illustration are in no way intended to be considered limiting. Further, the invention has been described with reference to particular preferred embodiments, but variations within the spirit and scope of the invention will occur to those skilled in the art. It is noted that the foregoing examples have been provided merely for the purpose of explanation and are in no way to be construed as limiting of the present invention. While the present invention has been described with reference to exemplary embodiments, it is understood that the words, which have been used herein, are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed is:

1. A resonator clock for use in downhole conditions comprising:
a resonator portion of piezoelectric material;
two electrodes in electrical communication with the resonator portion such that the resonator portion resonates when voltage is applied between the two electrodes; and
two or more supports to support the resonator portion, the supports being dimensioned and positioned to support the resonator portion under shock and vibration encountered in downhole use, wherein the supports and the resonator portion are formed from the same continuous piece of piezoelectric material.

2. A resonator clock according to claim 1 wherein the two or more supports includes four supports to support the resonator portion.

3. A resonator clock according to claim 1 wherein the piezoelectric material is crystalline quartz.

4. A resonator clock according to claim 1 further comprising:
one or more extended portions which extend from the two or more supports, the extended portions being formed from the same continuous piece of piezoelectric material as the supports and the resonator portion; and
two sealing portions each hermetically sealed to the one or more extended portions such that the resonator portion is maintained substantially in a vacuum environment.

5. A resonator clock according to claim 4 wherein the sealing portions are sealed to the one or more extended portions using a non-conductive and non-organic bonding agent.

6. A resonator clock according to claim 5 further comprising spacer portions sealed between the extended portions and the sealing portions.

7. A resonator clock according to claim 5 where the sealing portions are formed of the same type of material as the piezoelectric material.

8. A resonator clock according to claim 3 wherein the piezoelectric material is stress-compensated cut quartz crystal.

9. A resonator clock according to claim 3 wherein the piezoelectric material is Langasite or Langatite.

10. A resonator clock according to claim 1 wherein the electrodes are deposited directly onto the piezoelectric material of the resonator portion.

11. A resonator clock according to claim 1 wherein the resonator clock is a single-mode clock, and wherein the piezoelectric material is quartz crystal having a AT-cut or BT-cut crystalline orientation.

12. A resonator clock according to claim 1 wherein the resonator clock is a dual-mode clock, and wherein the piezoelectric material is quartz crystal having a crystalline orientation selected from a group consisting of: SC-Cut, RT-cut X+30o-cut, and SBTC-cut.

13. A method of making measurements downhole comprising:
positioning a downhole tool body in a wellbore; and
making measurements using the tool body in part by using a resonator clock that includes a resonator portion of piezoelectric material, two electrodes in electrical communication with the resonator portion such that the resonator portion resonates when voltage is applied between the two electrodes, and two or more supports to support the resonator portion, the supports being dimensioned and positioned to support the resonator portion under shock and vibration encountered in downhole use, wherein the supports and the resonator portion are formed from the same continuous piece of piezoelectric material.

14. A method according to claim 13 wherein the piezoelectric material is crystalline quartz.

15. A method according to claim 13 wherein the resonator clock further includes one or more extended portions which extend from the two or more supports, the extended portions being formed from the same continuous piece of piezoelectric material as the supports and the resonator portion, and two sealing portions each hermetically sealed to the one or more extended portions such that the resonator portion is maintained substantially in a vacuum environment.

16. A method according to claim 13 wherein the two or more supports includes four supports to support the resonator portion.

17. A method according to claim 13 wherein the tool body is an LWD or MWD module mounted on a drill collar, and the measurements are made during the a drilling operation.

18. A method according to claim 13 wherein the tool body forms part of a wireline toolstring which is positioned in the wellbore via a wireline cable.

19. A downhole tool comprising:
a tool body dimensioned and adapted to be deployed downhole in a wellbore; and
a resonator clock mounted within the tool body, the resonator clock including a resonator portion of piezoelectric material, two electrodes in electrical communication with the resonator portion such that the resonator portion resonates when voltage is applied between the two electrodes, and two or more supports to support the resonator portion, the supports being dimensioned and positioned to support the resonator portion under shock and vibration encountered in downhole use, wherein the supports and the resonator portion are formed from the same continuous piece of piezoelectric material.

20. A downhole tool according to claim 19 wherein the piezoelectric material is crystalline quartz.

21. A downhole tool according to claim 19 wherein the resonator clock further includes one or more extended portions which extend from the two or more supports, the extended portions being formed from the same continuous piece of piezoelectric material as the supports and the resonator portion, and two sealing portions each hermetically sealed to the one or more extended portions such that the resonator portion is maintained substantially in a vacuum environment.

22. A downhole tool according to claim 21 wherein the sealing portions are sealed to the one or more extended portions using a non-conductive and non-organic bonding agent.

23. A downhole tool according to claim 22 further comprising spacer portions sealed between the extended portions and the sealing portions.

24. A downhole tool according to claim 22 where the sealing portions are formed of the same type of material as the piezoelectric material.

25. A downhole tool according to claim 19 wherein the two or more supports includes four supports to support the resonator portion.

26. A downhole tool according to claim 20 wherein the piezoelectric material is stress-compensated cut quartz crystal.
